(19) United States
(12) Patent Application Publication
(10) Pub. No.: US 2026/0255540 A1
(43) Pub. Date: Aug. 27, 2026

(54) HEAT DISSIPATION MODULE

(71) Applicant: COOLER MASTER CO., LTD., Taipei City (TW)

(72) Inventors: Pin Chen WANG, Taipei City (TW); Wen-Ching CHEN, Taipei City (TW); Po-Wen TU, Taipei City (TW)

(73) Assignee: COOLER MASTER CO., LTD., Taipei City (TW)

(21) Appl. No.: 19/385,292

(22) Filed: Nov. 11, 2025

(30) Foreign Application Priority Data
Nov. 11, 2024 (TW) 113212264

(51) Int. Cl. H05K 7/20

(52) U.S. Cl. CPC H05K 7/20272; H05K 7/20254

(57) ABSTRACT

A heat dissipation module for cooling an optical transceiver module includes a cold plate having an internal flow channel and a heat absorption surface, the internal flow channel having an inlet port and an outlet port, and the heat absorption surface configured to thermally contact the optical transceiver module, an inlet pipe having a first end connected to the inlet port and a second end connected to a cooling device, and an outlet pipe having a first end connected to the outlet port and a second end connected to the cooling device, the outlet pipe is configured to be in fluid communication with the inlet pipe through the internal flow channel and the cooling device, and the outlet pipe, the internal flow channel, the cooling device and the inlet pipe form a cooling circulation loop.

### RELATED APPLICATIONS

This US application claims priority to Taiwan Application No. 113212264, filed on November 11, 2024, of which is incorporated herein by reference in its entirety.

### TECHNICAL FIELD

The present disclosure is related to the field of thermal management systems, in particular to heat dissipation modules having internal flow channels for forming cooling circuits.

### BACKGROUND

Currently, optical fibers are widely used as the primary network transmission medium in many countries throughout the world. Since optical fibers transmit signals through total internal reflection of light, they offer advantages of high-speed transmission and minimal transmission loss. When optical fibers are used as transmission media in network systems, they exhibit broadband, high-capacity, and high-speed properties. As the volume of information transmission increases and users seek higher network speeds, the transmission capacity of optical fibers progressively encounters obstacles.

As data transmission demands escalate, optical transceiver modules have heightened workloads, resulting in increased heat dissipation requirements. Optical transceiver modules generate significant heat in high data transmission rate settings, which, if not efficiently dissipated, can lead to performance degradation or component failure. Therefore, to maintain stable operation, modern network equipment usually needs advanced heat dissipation technology to meet the thermal management requirements of these optical transceiver modules.

### SUMMARY

Aspects of the disclosure provide a heat dissipation module for cooling an optical transceiver module. The heat dissipation module includes a cold plate having an internal flow channel and a heat absorption surface, the internal flow channel having an inlet port and an outlet port, and the heat absorption surface configured to thermally contact the optical transceiver module, an inlet pipe having a first end connected to the inlet port and a second end connected to a cooling device, and an outlet pipe having a first end connected to the outlet port and a second end connected to the cooling device, the outlet pipe is configured to be in fluid communication with the inlet pipe through the internal flow channel and the cooling device, and the outlet pipe, the internal flow channel, the cooling device and the inlet pipe form a cooling circulation loop.

In an embodiment, the cooling circulation loop is configured to contain a coolant, the inlet pipe is configured to transport the coolant cooled by the cooling device to the internal flow channel to absorb heat from the cold plate, and the outlet pipe is configured to transport the coolant that has absorbed heat in the internal flow channel to the cooling device.

In an embodiment, the cold plate can be made of copper alloy. In an embodiment, the internal flow channel can be a serpentine flow channel. In an embodiment, the openings of the inlet port and the outlet port face the same direction. In an embodiment, the internal flow channel can have a U-shape. In an embodiment, the inlet pipe is made of metal and the outlet pipe is made of metal. For example, the inlet pipe can be made of copper alloy and the outlet pipe can be made of copper alloy.

Aspects of the disclosure provide a heat dissipation module for cooling an optical transceiver module. The heat dissipation module includes a cooling device, a cold plate having an internal flow channel and a heat absorption surface, the internal flow channel having an inlet port and an outlet port, and the heat absorption surface configured to thermally contact the optical transceiver module, an inlet pipe having two ends respectively connected to the inlet port and the cooling device, and an outlet pipe having two ends respectively connected to the outlet port and the cooling device, the outlet pipe is configured to be in fluid communication with the inlet pipe through the internal flow channel and the cooling device, and the outlet pipe, the internal flow channel, the cooling device and the inlet pipe form a cooling circulation loop.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a perspective view of a heat dissipation module and a heat-generating assembly according to aspects of the present disclosure.

FIG. 2 illustrates a partially exploded view of the heat dissipation module and heat-generating assembly of FIG. 1.

FIG. 3 illustrates a partial and cross-sectional view of the heat dissipation module and heat-generating assembly of FIG. 1.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

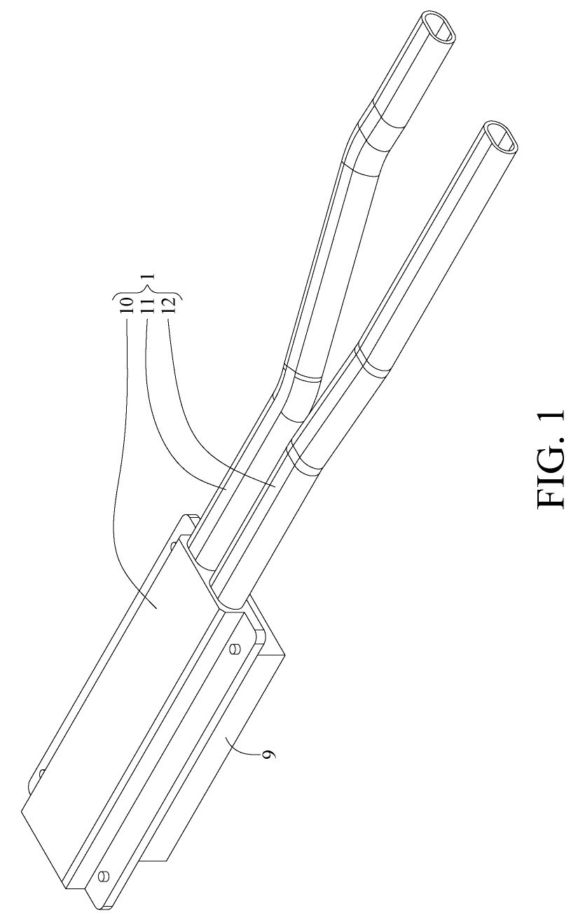

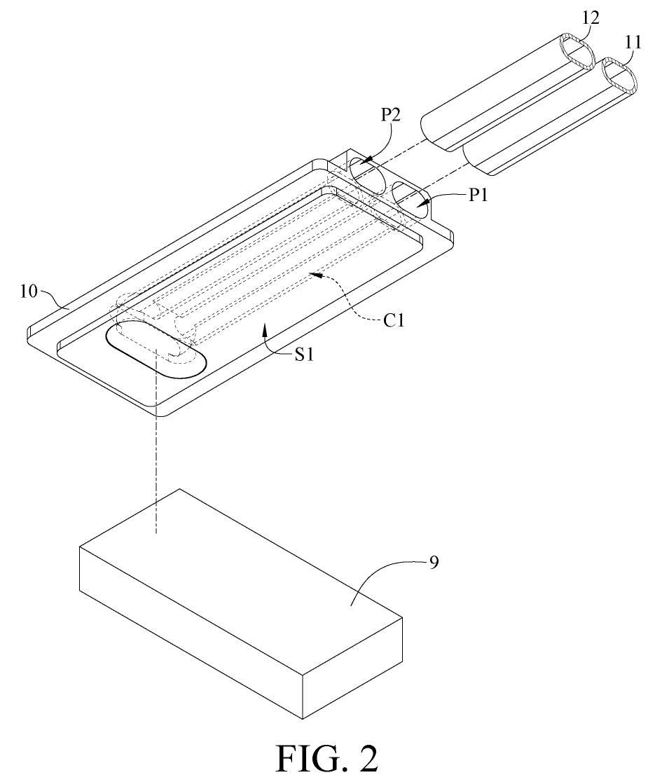

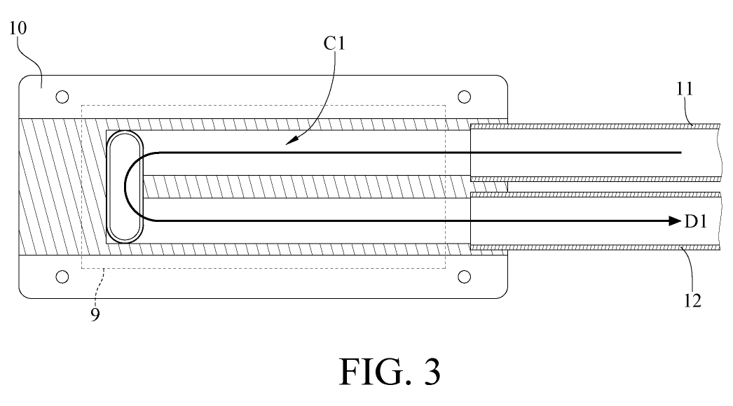

Please refer to FIGS. 1 to 3. FIG. 1 illustrates a perspective view of a heat dissipation module and a heat-generating assembly according to aspects of the present disclosure. FIG. 2 illustrates a partially exploded view of the heat dissipation module and heat-generating assembly of FIG. 1. FIG. 3 is a partially cross-sectional view of the heat dissipation module and heat-generating assembly of FIG. 1.

The heat dissipation module 1 is configured to cool the heat-generating assembly9, where the heat-generating assembly 9 may be, for example, an optical transceiver module such as a Quad Small Form-factor Pluggable (QSFP) optical transceiver module. The heat dissipation module 1 is specifically designed to address the increasing thermal management challenges faced by modern optical transceiver modules that operate at high data transmission rates, generating substantial heat that must be effectively dissipated to prevent performance degradation or component damage.

The heat dissipation module 1 includes a cold plate 10, an inlet pipe 11, an outlet pipe 12, and a cooling device (not shown). The cold plate 10 has an internal flow channel C1 and a heat absorption surface S1, where the internal flow channel C1 has an inlet port P1 and an outlet port P2. The heat absorption surface S1 is in thermally contact with the optical transceiver module 9. The heat absorption surface S1 is configured to optimize thermal contact with the optical transceiver module 9, facilitating effective heat transfer from the heat-generating assembly to the cold plate 10. The internal flow channel C1 is appropriately located within the cold plate 10 to optimize heat absorption from the heat absorption surface S1.

The inlet pipe 11 has two ends respectively connected to the inlet port P1 and the cooling device, and the outlet pipe 12 has two ends respectively connected to the outlet port P2 and the cooling device. The outlet pipe 12 is in fluid communication with the inlet pipe 11 through the internal flow channel C1 and the cooling device. Together, the inlet pipe 11, outlet pipe 12, internal flow channel C1, and cooling device form a cooling circulation circuit. The cooling circulation circuit is configured to contain a coolant, while the cooling device is configured to cool and pump the coolant. The inlet pipe 11 is configured to circulate the cooled coolant along a circulation direction D1 to the internal flow channel C1, where it absorbs heat from the cold plate 10, which has been absorbed from the optical transceiver module 9. The outlet pipe 12 is configured to circulate the heated coolant in the internal flow channel C1 back to the cooling device along the same circulation direction D1. The coolant can be water or organic fluids such as propane and pentane, but the present disclosure is not limited to these specific coolant types. The cooling device may include a pump (not shown) and a heat dissipating device (not shown), with the pump configured to circulate the coolant and the heat dissipating device is configured to dissipate heat from the coolant.

As shown in FIG. 3, the internal flow channel C1 of the cold plate 10 may have a U-shape, and the openings of both inlet port P1 and outlet port P2 of the internal flow channel C1 may face the same side. Allowing the internal flow channel C1 to be distributed over a large area within the cold plate 10 increases the contact area between the coolant and the cold plate 10, which improves heat transfer efficiency. However, the present disclosure is not limited to the U-shaped configuration of the internal flow channel C1.Alternatively,, the internal flow channel C1 may be configured as other types of serpentine or meandering flow channels, such as S-shaped flow channels or M-shaped flow channels, to further enhance heat transfer efficiency. The serpentine configuration increases the coolant’s residence time within the cold plate 10, facilitating enhanced heat absorption. The heat dissipating device of the cooling device may include, for example, heat dissipating fins, a fan, a liquid cooling radiator, or a heat conducting plate; however, the present disclosure is not limited to these specific configurations.

In one embodiment, the cold plate 10 can be made of copper alloy (Cu1100), as can the inlet pipe 11 and the outlet pipe 12. The use of copper alloy provides excellent thermal conductivity properties, allowing for effective heat transfer from the optical transceiver module 9 to the coolant running through the internal flow channel C1. In other embodiments , the cold plate 10, inlet pipe 11, and outlet pipe 12 can be made of other metallic materials with high thermal conductivity, including but not limited to aluminum alloy, stainless steel, nickel alloy, or titanium alloy. The selectin of materials can be refined based on specific thermal performance requirements, cost considerations, and compatibility with the used coolant. The metallic compositions of these components ensures durability and reliable thermal performance during prolonged operational durations.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. A heat dissipation module for cooling an optical transceiver module, the heat dissipation module comprising:
a cold plate having an internal flow channel and a heat absorption surface, the internal flow channel having an inlet port and an outlet port, and the heat absorption surface configured to thermally contact the optical transceiver module;
an inlet pipe having a first end connected to the inlet port and a second end connected to a cooling device; and
an outlet pipe having a first end connected to the outlet port and a second end connected to the cooling device, the outlet pipe is in fluid communication with the inlet pipe through the internal flow channel and the cooling device, and the outlet pipe, the internal flow channel, the cooling device and the inlet pipe form a cooling circulation loop.

2. The heat dissipation module of claim 1, wherein the cooling circulation loop is configured to contain a coolant, the inlet pipe is configured to transport the coolant cooled by the cooling device to the internal flow channel to absorb heat from the cold plate, and the outlet pipe is configured to transport the coolant that has absorbed heat in the internal flow channel to the cooling device.

3. The heat dissipation module of claim 1, wherein the cold plate is made of copper alloy.

4. The heat dissipation module of claim 1, wherein the internal flow channel is a serpentine flow channel.

5. The heat dissipation module of claim 1, wherein openings of the inlet port and the outlet port face the same direction.

6. The heat dissipation module of claim 1, wherein the internal flow channel has a U-shape.

7. The heat dissipation module of claim 1, wherein the inlet pipe is made of metal and the outlet pipe is made of metal.

8. The heat dissipation module of claim 7, wherein the inlet pipe is made of copper alloy and the outlet pipe is made of copper alloy.

9. A heat dissipation module for cooling an optical transceiver module, the heat dissipation module comprising:
a cooling device;
a cold plate having an internal flow channel and a heat absorption surface, the internal flow channel having an inlet port and an outlet port, and the heat absorption surface configured to thermally contact the optical transceiver module;
an inlet pipe having two ends respectively connected to the inlet port and the cooling device; and
an outlet pipe having two ends respectively connected to the outlet port and the cooling device, the outlet pipe is in fluid communication with the inlet pipe through the internal flow channel and the cooling device, and the outlet pipe, the internal flow channel, the cooling device and the inlet pipe form a cooling circulation loop.

10. The heat dissipation module of claim 9, wherein the cooling circulation loop is configured to contain a coolant, the cooling device is configured to pump and cool the coolant, the inlet pipe is configured to transport the cooled coolant to the internal flow channel to absorb heat from the cold plate, and the outlet pipe is configured to transport the coolant that has absorbed heat in the internal flow channel to the cooling device.

11. The heat dissipation module of claim 9, wherein the cooling device includes a pump and a heat dissipating device, the pump configured to pump the coolant, and the heat dissipating device configured to cool the coolant.

12. The heat dissipation module of claim 11, wherein the heat dissipating device includes a heat dissipating fin, a fan, a liquid cooling radiator, or a heat conducting plate.
